(19) United States
(12) Patent Application Publication
(10) Pub. No.: US 2007/0114572 A1
(43) Pub. Date: May 24, 2007

(54) Gate structure including multi-tunneling layer and method of fabricating the same, non-volatile memory device and method of fabricating the same

(75) Inventors: Kwang-Soo Seol, Suwon-si (KR); Woong-Chul Shin, Suwon-si (KR); Byung Ki Kim, Gunpo-si (KR); Eun-Kyung Lee, Suwon-si (KR); Kyung-Sang Cho, Gwacheon-si (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 11/600,737

(22) Filed: Nov. 17, 2006

(30) Foreign Application Priority Data
Nov. 19, 2005 (KR) 10-2005-0111046

(51) Int. Cl. H01L 29/76

(52) U.S. Cl. 257/213

(57) ABSTRACT

Provided is a gate structure including a multi-tunneling layer and method of fabricating the same. Also provided is a nanodot semiconductor memory device including such gate structure and method of fabricating the same. The gate structure may include a first insulation layer, a second insulation layer, a charge storage layer including nanodots and formed on the second insulation layer, a third insulation layer formed on the charge storage layer, and a gate electrode layer formed on the third insulation layer. There may also be a nanodot semiconductor memory device including a semiconductor substrate, in which a first impurity region and a second impurity region may be formed, and including the gate structure formed on the semiconductor substrate which contacts the first and second impurity regions. The second insulation layer may be formed on the first insulation layer and may include a material whose energy level may be lower than an energy level of the conduction band of the first insulation layer and higher an energy level of the valence band of the first insulation layer.

### PRIORITY STATEMENT

This application claims priority under 35 USC § 119 to Korean Patent Application No. 2005-011-1046, filed on Nov. 19, 2005, in the Korean Intellectual Property Office (KIPO), the entire contents of which are herein incorporated by reference.

### BACKGROUND

1. Field

Example embodiments relate to a gate structure including a multi-tunneling layer including a plurality of layers of dielectric material with varying energy band gaps and method of fabricating the same. Example embodiments also relate to a non-volatile memory device including such gate structure and method of fabricating the same. As such, the memory device may have improved data recording and storing capabilities.

2. Description of the Related Art

Due to the development of the multimedia device industry, the demand for information storage devices has increased. Semiconductor memory devices are being researched and designed in consideration of information storage density, data recording speed, and/or data erasing speed. Accordingly, various types of semiconductor memory devices are being developed.

Conventional semiconductor memory devices may be classified into volatile memory devices and non-volatile memory devices. Volatile memory devices include dynamic random access memories (DRAMs) and static random access memories (SRAMs). When power is supplied to volatile memory devices, they may input and output data at a higher speed. However, when the power supply to the volatile memory devices is terminated, data in the volatile memory devices is lost. On the other hand, non-volatile memory devices retain data even when the power supply is terminated. A flash memory device is an example of a non-volatile memory device.

FIG. 1 is a cross-sectional view of a conventional nanodot memory device, which may act as a non-volatile memory device.

A first impurity region 11a and a second impurity region 11b may be formed in a semiconductor substrate 10. A gate structure may be formed to contact the first and second impurity regions 11a and 11b. The gate structure may include a tunneling layer 12, a charge storage layer 13 further including nanodots 14, and/or a gate electrode layer 15 stacked sequentially.

Information may be recorded in the conventional nanodot memory device illustrated in FIG. 1 using a Fowler-Nordheim (F-N) tunnel injection method. When electrons pass through the tunneling layer 12, they may become trapped in the nanodots 14, which act as a trap site of the charge storage layer 13. Information may then be recorded in the conventional nanodot memory device.

The tunneling layer 12 may be formed of a dielectric material, for example, SiO₂. When a thickness of the tunneling layer 12 is equal to or less than approximately 2.0 nm, electrons directly tunneled in a channel region of the semiconductor substrate 10 may be injected. Therefore, information may be recorded at a speed of tens of nanoseconds (ns). However, when the thickness of the tunneling layer 12 is equal to or less than approximately 2.0 nm, electrons stored in the charge storage layer 13 may more easily leak through the tunneling layer 12. Therefore, retention characteristics (the ability to store electric charges for a longer time) of the charge storage layer 13 may be undermined. In addition, holes having opposite charges may tunnel through the tunneling layer 12 from the semiconductor substrate 10. Because the holes offset electrons preserved in the nanodots 14, the retention characteristics may further deteriorate.

Because non-volatile memory devices may be required to retain data for more than 10 years at room temperature, their retention characteristics must be enhanced. Therefore, efforts have been made to improve the material and/or structure of a tunneling layer. For example, a nanodot memory using a tunneling layer formed of HfO₂, which is a high-k thin film, has been disclosed.

A memory window of approximately 0.2 V may be obtained when data is programmed into a nanodot memory at a speed of 100 ms. Also, 25% of the initial electric charges accumulated in nanodots may be lost during 5×10⁴ s data retention. The characteristics of a nanodot memory device including a tunneling layer formed of HfO₂ may be better than those of a nanodot memory device including a tunneling layer formed of SiO₂. However, the characteristics of a nanodot memory of a NAND or a NOR flash memory (e.g., a memory window of 3 V or higher and a 5% or less reduction in the initial electric charges during 10 years of data retention) including a tunneling layer formed of HfO₂ may be worse.

Additional research discloses a nanodot memory including a SiO₂ tunneling layer with a thickness of 1.8 nm, a charge storage layer having a Si nanocrystal and a Si₃N₄ layer with a thickness of 9 nm, and a SiO₂ control oxide layer with a thickness of 5 nm. In such a nanodot memory, a threshold voltage change of 0.2 V is obtained at the programming speed of 1 ms by direction tunneling. However, because the data retention of the nanodot memory may be shorter, the nanodot memory may not be applied to flash memories requiring 10 years of data retention.

A memory with an asymmetric tunneling barrier structure has been suggested as one way to address such technological problems.

As an example of a material structure, a tunneling layer may include a SiO₂ layer of 5 A and a Si₃N₄ layer of 10 A overlapping each other. Assuming that a conduction band offset value between Si₃N₄ and Si is 2.1 V, if a voltage of 2.1 V or higher is applied to the SiO₂ layer of 5A, direct tunneling may occur. Accordingly, data may be programmed at higher speed. However, because the voltage of 2.1 V may be converted into an electric field value of almost 40 MV/cm, the dielectric breakdown of the SiO₂ layer may be unavoidable. Therefore, the SiO₂ layer and the Si₃N₄ layer may not be used as a tunneling layer of a memory device.

Another silicon nanodot memory using an SiO₂ layer with a thickness of 2 nm and an amorphous carbon layer with a thickness of 1.3 nm as a tunneling layer has been disclosed. However, when the SiO₂ layer is deposited, the amorphous carbon layer reacts with oxygen and therefore, may evaporate. Thus, the amorphous carbon layer may not be used to fabricate the silicon nanodot memory. In addition, because the amorphous carbon layer has a relatively thin thickness of 1.3 nm, electric charges accumulated in nanodots may easily discharge to a semiconductor substrate.

### SUMMARY

Example embodiments provide a gate structure which may include a charge storage layer with improved data retention characteristics and method of fabricating the same. Example embodiments also provide a non-volatile memory device including such gate structure and method of fabricating the same. As such, the memory device may have faster data recording and/or faster data erasing capabilities.

According to example embodiments, a gate structure may include a first insulation layer, a second insulation layer, a charge storage layer on the second insulation layer and including nanodots, a third insulation layer on the charge storage layer, and a gate electrode layer on the third insulation layer. There may also be a semiconductor memory device including a semiconductor substrate, which includes a first impurity region and a second impurity region, and including the gate structure on the semiconductor substrate which contacts the first and second impurity regions.

The second insulation layer may be formed on the first insulation layer and may include a material whose energy level may be lower than the energy level of the conduction band of the first insulation layer and higher than the energy level of the valence band of the first insulation layer.

The second insulation layer may have a thickness sufficient to reduce or prevent direct tunnelling. Thus, the second insulation layer may reduce or prevent holes from ejecting from the semiconductor substrate, thereby enhancing the retention characteristics of the charge storage layer.

Example embodiments provide a method of fabricating a gate structure that may include forming a first insulation layer, forming a second insulation layer, forming a charge storage layer including nanodots on the second insulation layer, forming a third insulation layer on the charge storage layer, and forming a gate electrode layer on the third insulation layer. There may also be a method of fabricating a semiconductor memory device that may include providing a semiconductor substrate including a first impurity region and a second impurity region and forming the gate structure on the semiconductor substrate in which the gate structure contacts the first and second impurity regions.

The first insulation layer may be formed of SiO₂ and the thickness may be in the range of about 1 nm to 3 nm. The second insulation layer may be formed of at least one selected from the group including TiO₂, Ta₂O₅, HfO₂, ZrO₂, TiO₂, Y₂O₃, La₂O₃, HfOₓN_{y}, HfSiOₓN_{y}, ZrSiOₓN_{y}, and ZrOₓN_{y}. The thickness of the second insulation layer may be in the range of about 3 nm to 10 nm. The third insulation layer may be formed of a material whose permittivity is greater than that of the first insulation layer and may be formed of at least one selected from the group including SiO₂, Al₂O₃, Si₃N₄, HfO₂, ZrO₂, TiO₂, Y₂O₃, La₂O₃, and ZrSiO₄.

The nanodots may be formed of a single metal material having relatively large work function (e.g., Ni, Pt, Fe, Co, Pd, or Ir), a material containing any one of a nitride-base metal material (e.g., TiN or TaN), an oxide metal material (e.g., RuOx), and/or a metal silicide of the single metal material.

### BRIEF DESCRIPTION OF THE DRAWINGS

Example embodiments will be more clearly understood from the following detailed description taken in conjunction with the accompanying drawings. FIGS. 1-8 represent non-limiting, example embodiments as described herein.

FIG. 1 is a cross-sectional view of a conventional nanodot memory device, which acts as a non-volatile memory device;

FIG. 2 is a cross-sectional view of a non-volatile memory device including a multi-tunnelling layer according to example embodiments;

FIG. 3 is an example energy band diagram of the non-volatile memory device of FIG. 2;

FIGS. 4A and 4B are example energy band diagrams of the non-volatile memory device of FIG. 2 performing a data writing operation;

FIG. 5 is an example energy band diagram illustrating the retention characteristics of the non-volatile memory device of FIG. 2;

FIGS. 6A and 6B are example energy band diagrams of the non-volatile memory device of FIG. 2 illustrating when electric charges are stored in nanodots as in FIG. 5 and illustrating the device performing a data erasing operation, respectively;

FIG. 7 is an example graph illustrating variations in a flat band voltage according to a voltage applied to the non-volatile memory device of FIG. 2; and

FIG. 8 is an example graph illustrating variations over time of an initial memory window value of the non-volatile memory device of FIG. 2.

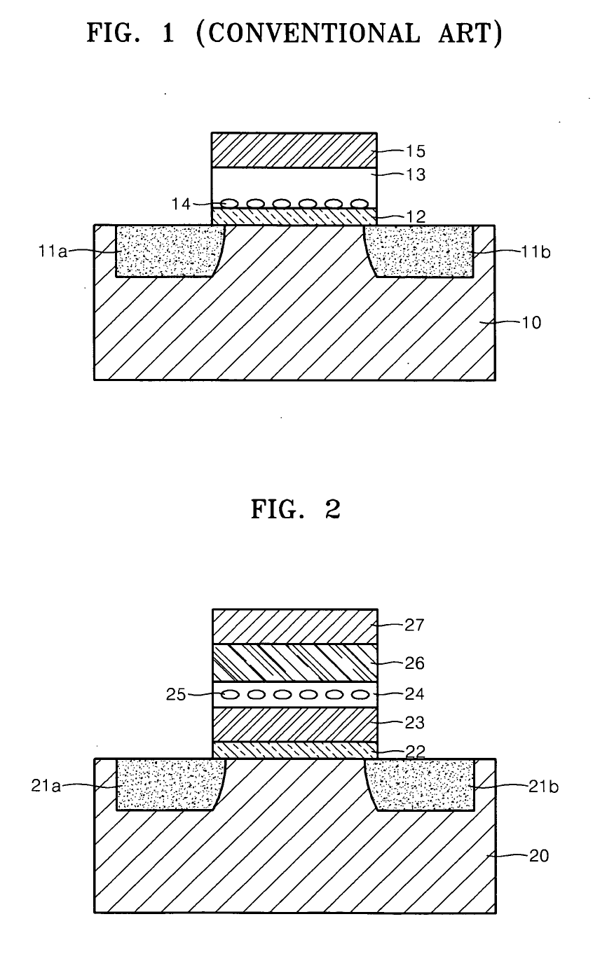

### DETAILED DESCRIPTION OF EXAMPLE EMBODIMENTS

Reference will now be made in detail to example embodiments, examples of which are illustrated in the accompanying drawings. However, example embodiments are not limited to the embodiments illustrated hereinafter, and the embodiments herein are rather introduced to provide easy and complete understanding of the scope and spirit of example embodiments. In the drawings, the thicknesses of layers and regions are exaggerated for clarity.

It will be understood that when an element or layer is referred to as being “on,” “connected to” or “coupled to” another element or layer, it may be directly on, connected or coupled to the other element or layer or intervening elements or layers may be present. In contrast, when an element is referred to as being “directly on,” “directly connected to” or “directly coupled to” another element or layer, there are no intervening elements or layers present. Like reference numerals refer to like elements throughout. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of example embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” may encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of example embodiments (and intermediate structures). As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle may, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of example embodiments.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

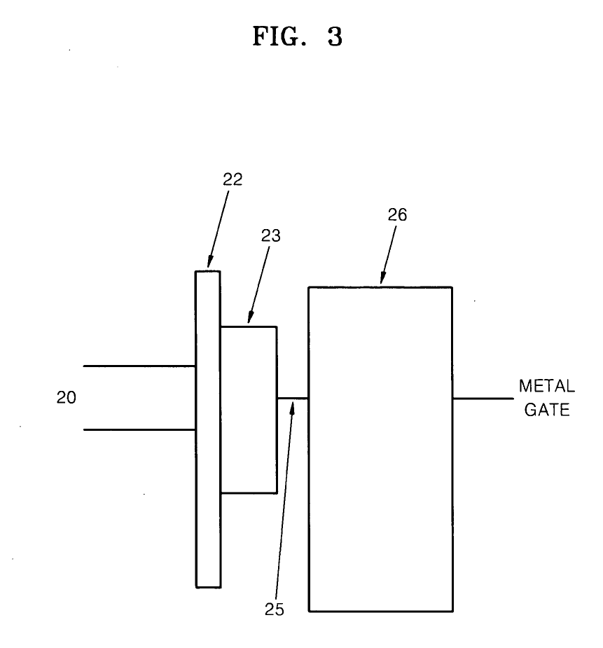

FIG. 2 is a cross-sectional view of a non-volatile memory device including a multi-tunnelling layer according to example embodiments. FIG. 3 is an energy band diagram of the non-volatile memory device of FIG. 2 illustrating the state before power is supplied.

Referring to FIGS. 2 and 3, a first impurity region 21a and a second impurity region 21b may be formed in a semiconductor substrate 20. A channel region may be formed between the first and second impurity regions 21a and 21b. A gate structure, contacting both the first and second impurity regions 21a and 21b, may be formed on the channel region. The gate structure may include a first insulation layer 22, a second insulation layer 23, a charge storage layer 24 further including nanodots 25, a third insulation layer 26, and/or a gate electrode layer 27, for example, stacked sequentially.

The first insulation layer 22 and second insulation layer 23, which may collectively form a tunnelling layer, may be formed of n number of dielectric materials, where n is greater than or equal to 2.

The first insulation layer 22 may be formed to a thickness which allows for easier tunnelling of electrons or holes. In an example embodiment, when the first insulation layer 22 is formed of SiO₂, the first insulation layer 22 may have a thickness within the range of about 1 nm to 3 nm. The first insulation layer 22, formed of SiO₂ for example, may be a silicon oxide layer formed using a thermal oxide layer after an original oxide layer has been reduced or removed from a silicon substrate. The first insulation layer 22 may also be formed using a silicon insulation layer containing nitride formed after the silicon oxide layer undergoes a nitride heat treatment process.

The second insulation layer 23 may be formed to a thickness which makes it more difficult for electrons or holes to tunnel through. The energy level of the conduction band of the second insulation layer 23 may be higher than the energy level of silicon and lower than an energy level of the first insulation layer 22. In addition, the energy level of the valence band of the second insulation layer 23 may be lower than the energy level of silicon and higher than an energy level of the first insulation layer 22. The second insulation layer 23 may be formed of TiO₂, Ta₂O₅, HfO₂, ZrO₂, TiO₂, Y₂O₃, La₂O₃, HfOₓN_{y}, HfSiOₓN_{y}, ZrSiOₓN_{y}, and/or ZrOₓN_{y}. The thickness of the second insulation layer 23 may be approximately equal to or greater than 3 nm (e.g., within the range of about 4 nm to 10 nm).

The nanodots 25 may be formed of a single metal material (e.g., Ni, Pt, Fe, Co, Pd, or Ir), a material containing any one of a nitride-base metal material (e.g., TiN or TaN), an oxide metal material (e.g., RuOx), and/or a metal silicide of the single metal material. The charge storage layer 24 may be formed of Si₃N₄, Al₂O₃, HfO₂, Ta₂O₅, and/or ZrO₂.

The third insulation layer 26 and the first or second insulation layer 22 or 23 may be formed of identical material. The permittivity of the third insulation layer 26 may be equal to or greater than that of the first insulation layer 22. The third insulation layer 26 may be formed of TiO₂, Ta₂O₅, HfO₂, ZrO₂, Y₂O₃, La₂O₃, HfOₓN_{y}, HfSiOₓN_{y}, and/or ZrSiOₓN_{y}. The gate electrode layer 27 may be formed of a conductive electrode material conventionally used in semiconductor devices.

Example operation principles of the non-volatile memory device of FIG. 2 will now be described in detail with reference to the attached drawings.

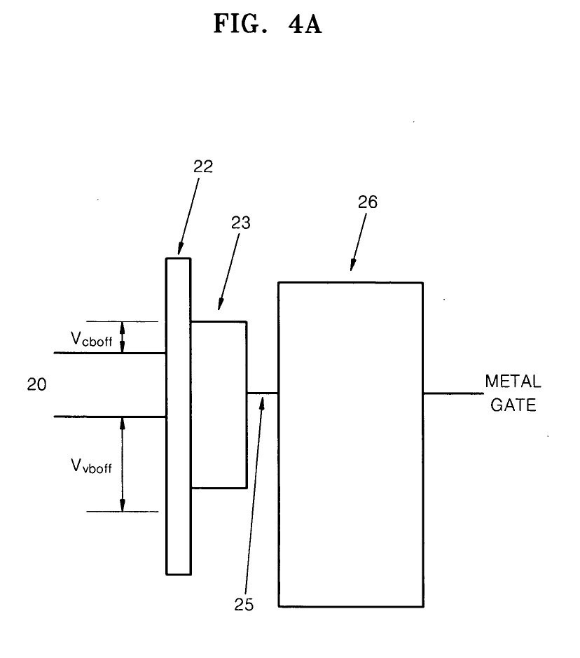

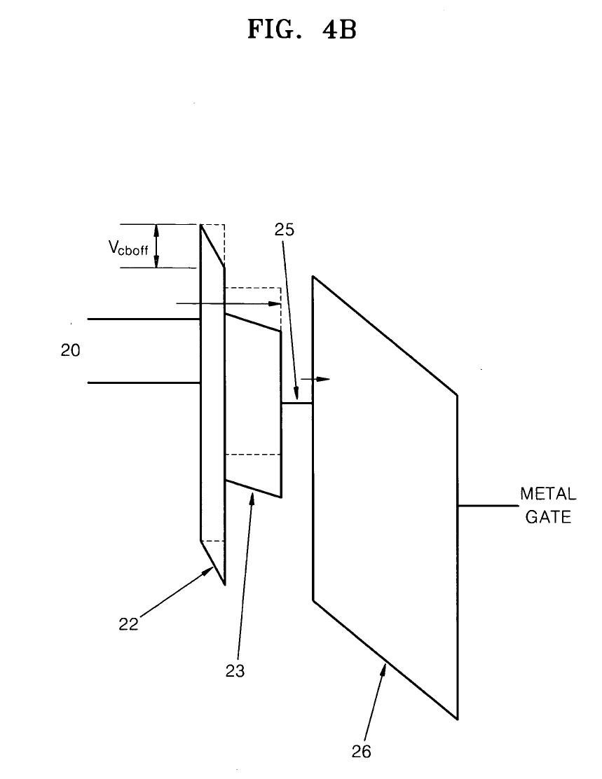

FIGS. 4A and 4B are example energy band diagrams of the non-volatile memory device of FIG. 2 performing a data writing operation. As in FIG. 3, FIG. 4A illustrates the state before power is supplied to the non-volatile memory device. FIG. 4B is the energy band diagram of the non-volatile memory device while being supplied with power via the gate electrode layer 27.

Referring to FIGS. 4A and 4B, when a predetermined or given positive voltage is applied to the non-volatile memory device via the gate electrode layer 27, an energy band of the non-volatile memory device is tilted as illustrated in FIG. 4B. In example embodiments, when a voltage equal to or greater than V_{cboff} is applied to the first insulation layer 22, the energy level of the conduction band of the second insulation layer 23 becomes lower than the energy level of the conduction band of the semiconductor substrate 20 (e.g., a silicon substrate). At this time, electrons in the conduction band of the semiconductor substrate 20 directly tunnel through the first insulation layer 22. Consequently, a larger number of electric charges may form within the nanodots 25 of the charge storage layer 24 within a shorter period of time.

The first insulation layer 22 may be formed of SiO₂ with a thickness of about 1.7 nm, the second insulation layer 23 may be formed of HfO₂ with a thickness of about 5 nm, and the third insulation layer 26 may be formed of HfO₂ with a thickness of about 10 nm. When a voltage of 0 V is applied to the semiconductor substrate 20 (e.g., a silicon substrate), and a voltage equal to or greater than 11 V is applied to the gate electrode layer 27, V_{cboff} is greater than approximately 1.5 V. Thus, the energy band diagram illustrated in FIG. 4B is obtained, and faster data programming is possible because electrons directly tunnelled from the Si substrate into the nanodots.

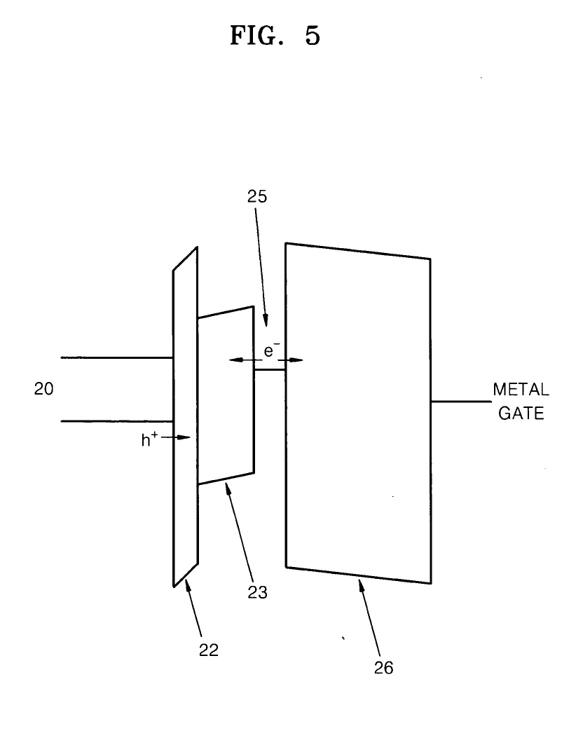

Example retention characteristics of the non-volatile memory device of FIG. 2 will now be described with reference to FIG. 5.

FIG. 5 is an example energy band diagram illustrating the retention characteristics of the non-volatile memory device of FIG. 2. When electrons directly tunnel though the first insulation layer 22 from the semiconductor substrate 20 and electric charges are formed within the nanodots 25 of the charge storage layer 24, information may be recorded on the non-volatile memory device. When no power is supplied, the non-volatile memory device has the energy band diagram illustrated in FIG. 5.

The first insulation layer 22, the second insulation layer 23, and/or the third insulation layer 26 may be formed to have thicknesses sufficient to reduce or prevent direct tunnelling of the electrons and the formation of electric charges within the nanodots 25 of the charge storage layer 24, thereby preserving information. Because the second insulation layer 23 has a thickness sufficient to reduce or prevent direct tunnelling, the second insulation layer 23 may reduce or prevent holes from ejecting from the semiconductor substrate 20, thereby enhancing the retention characteristics of the charge storage layer 24. Similarly, holes stored in the nanodots 25 may be prevented from-leaking to the semiconductor substrate 20 via the first and second insulation layers 22 and 23 and from ejecting to the gate electrode layer 27 via the third insulation layer 26. Because the sufficiently thick second insulation layer 23 reduces or prevents electrons from ejecting from the semiconductor substrate 20 into the nanodots 24, the holes may be preserved for a longer period of time, thereby enhancing the retention characteristics of the charge storage layer 24.

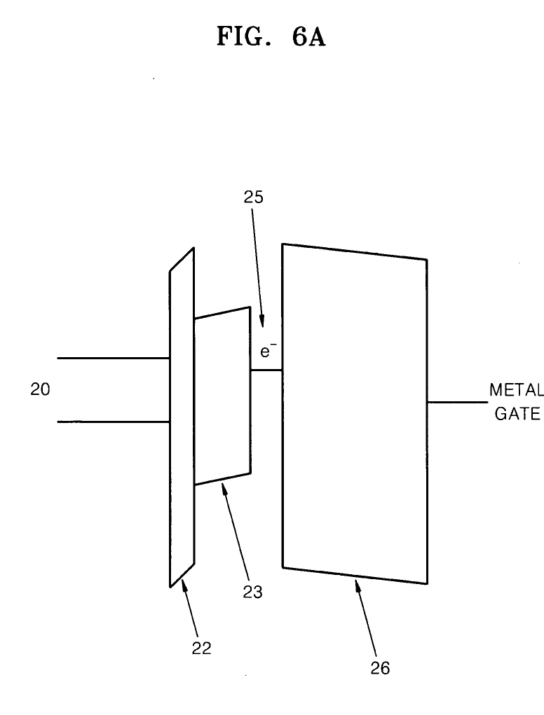

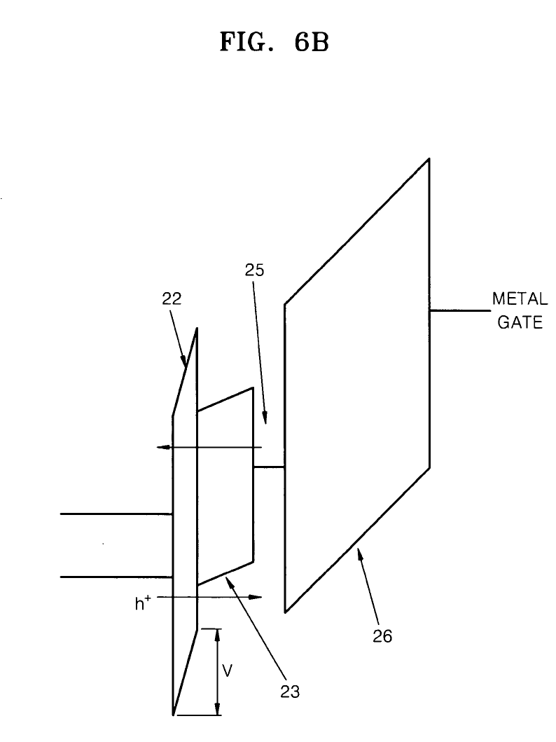

An example data erasing operation performed by the non-volatile memory device of FIG. 2 will now be described with reference to FIGS. 6A and 6B.

FIG. 6A is an example energy band diagram of the non-volatile memory device of FIG. 2 when electric charges are stored within the nanodots 25 as in FIG. 5. FIG. 6B is an example energy band diagram of the non-volatile memory device of FIG. 2 when power is supplied and data is erased from the nanodots 25 of the charge storage layer 24.

Referring to FIGS. 6A and 6B, when a predetermined or given negative voltage is applied to the gate electrode layer 27, an energy band of the non-volatile memory is tilted as illustrated in FIG. 6B. In example embodiments, when a voltage equal to or greater than V_{vboff} is applied to the first insulation layer 22, the energy level of the valence band of the second insulation layer 23 becomes higher than the energy level of the valence band of the semiconductor substrate 20 (e.g., a silicon substrate). At this time, holes in the valence band of the semiconductor substrate 20 directly tunnel through the first insulation layer 22. Consequently, a larger number of holes may be ejected into the nanodots 25 of the charge storage layer 24 within a shorter period of time.

The first insulation layer 22 may be formed of SiO₂ with a thickness of about 1.7 nm, the second insulation layer 23 may be formed of HfO₂ with a thickness of about 5 nm, and the third insulation layer 26 may be formed of HfO₂ with a thickness of about 10 nm. When a voltage of 0 V is applied to the silicon substrate and a voltage equal to or greater than 11 V is applied to the gate electrode layer 27, VvbOff is greater than approximately 3.4 V, and the example energy band diagram illustrated in FIG. 6B is obtained. Because approximately 17 A/cm² of holes were injected into the nanodots 25 of the charge storage layer 24 by direct tunnelling for approximately 24 ns, data may be erased at a faster speed.

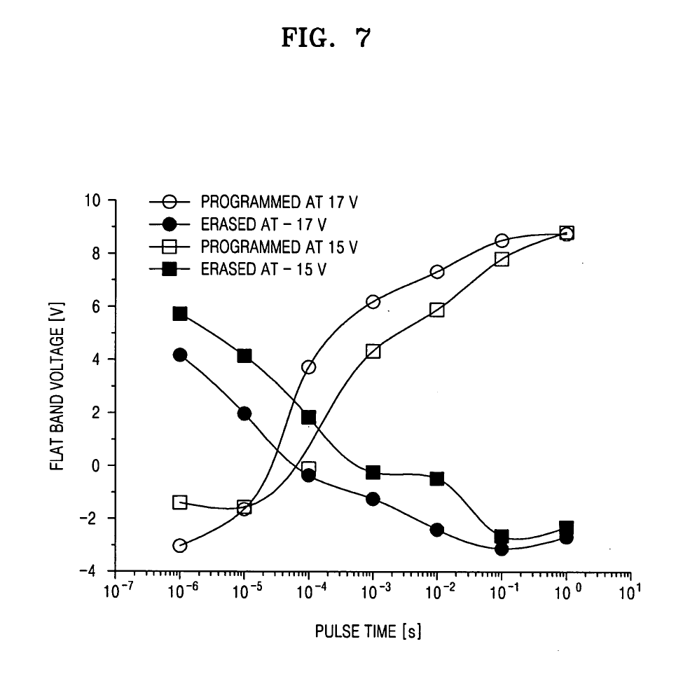

FIG. 7 is an example graph illustrating variations in a flat band voltage according to a voltage being applied to the non-volatile memory device of FIG. 2.

FIG. 7 illustrates variations in the flat band voltage of the non-volatile memory device each time a voltage of 15 V or 17 V is applied to the gate electrode layer 27 of the non-volatile memory device to program data and a voltage of −15 V or −17 V is applied to the gate electrode layer 27 to erase data. When data is programmed at 17 V for 100 ms and is erased at −17 V for 10 ms, a variation value of approximately 6 V may occur in the flat band voltage, which may be defined as a memory window value.

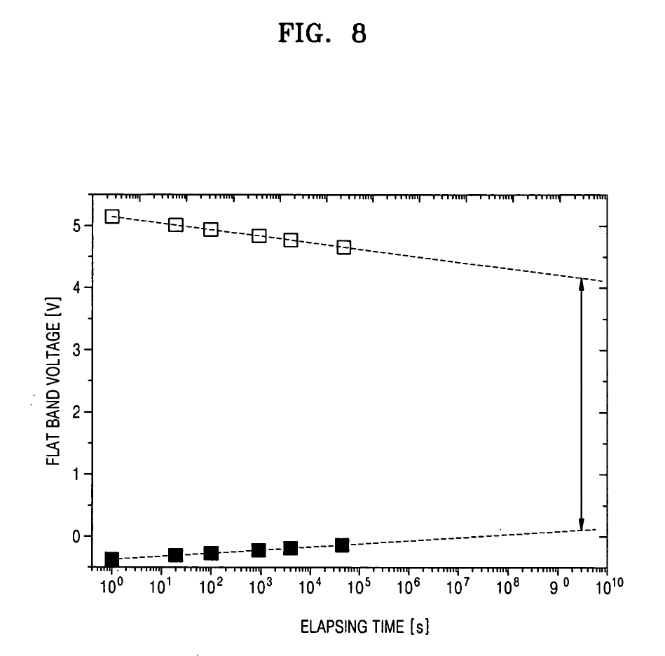

FIG. 8 is an example graph illustrating variations over time of an initial memory window value of the non-volatile memory device of FIG. 2.

Referring to FIG. 8, when data is programmed for 300 ms and erased for 1 ms by applying a voltage of 15 V to the gate electrode layer 27, extrapolation up to 3×109, corresponding to 10 years, shows that a memory window value of approximately 4 V or higher may be obtained after 10 years.

As described above, a non-volatile semiconductor memory device according to example embodiments may include a tunneling barrier layer which may be formed of dielectric material with varying energy band gaps and thus, may have improved data retention, recording, and/or storing characteristics.

The foregoing is illustrative of example embodiments and is not to be construed as limiting thereof. Although example embodiments have been described, those skilled in the art will readily appreciate that many modifications are possible in example embodiments without materially departing from the novel teachings and advantages of example embodiments. Accordingly, all such modifications are intended to be included within the scope of the claims. In the claims, means-plus-function clauses are intended to cover the structures described herein as performing the recited function, and not only structural equivalents but also equivalent structures. Therefore, it is to be understood that the foregoing is illustrative of example embodiments and is not to be construed as limited to the specific embodiments disclosed, and that modifications to the disclosed embodiments, as well as other embodiments, are intended to be included within the scope of the appended claims. Example embodiments are defined by the following claims, with equivalents of the claims to be included therein.

What is claimed is:

1. A gate structure comprising:
a first insulation layer;
a second insulation layer on the first insulation layer and including a material with a lower energy level than an energy level of a conduction band of the first insulation layer and a higher energy level than an energy level of a valence band of the first insulation layer;
a charge storage layer on the second insulation layer and including nanodots;
a third insulation layer on the charge storage layer; and
a gate electrode layer on the third insulation layer.

2. A semiconductor memory device comprising:
a semiconductor substrate including a first impurity region and a second impurity region; and
the gate structure of claim 1 on the semiconductor substrate and contacting the first and second impurity regions.

3. The gate structure of claim 1, wherein the first insulation layer has a thickness of about 0.5 nm through 2 nm.

4. The gate structure of claim 1, wherein the second insulation layer includes at least one material selected from the group including Si₃N₄, HfO₂, ZrO₂, TiO₂, Y₂O₃, La₂O₃, and ZrSiO₄.

5. The gate structure of claim 4, wherein the second insulation layer has a thickness of about 4 nm through 10 nm.

6. The gate structure of claim 1, wherein the nanodots include at least one of a metal and a semiconductor material.

7. The gate structure of claim 6, wherein the metal is selected from the group consisting of Ni, Cu, Pd, Au, Ag, Fe, Co, Mn, Cr, V, Mo, Nb and Ru.

8. The gate structure of claim 6, wherein the semiconductor material is selected from the group consisting of Si and Se.

9. The gate structure of claim 1, wherein the third insulation layer includes a material whose permittivity is greater than that of the first insulation layer.

10. The gate structure of claim 9, wherein the third insulation layer includes at least one material selected from the group including SiO₂, A1₂O₃, Si₃N₄, HfO₂, ZrO₂, TiO₂, Y₂O₃, La₂O₃, and ZrSiO₄.

11. A method of fabricating a gate structure, the method comprising:
forming a first insulation layer;
forming a second insulation layer on the first insulation layer which includes a material with a lower energy level than an energy level of a conduction band of the first insulation layer and a higher energy level than an energy level of a valence band of the first insulation layer;
forming a charge storage layer including nanodots on the second insulation layer;
forming a third insulation layer on the charge storage layer; and
forming a gate electrode layer on the third insulation layer.

12. A method of fabricating a semiconductor memory device, the method comprising:
providing a semiconductor substrate including a first impurity region and a second impurity region; and
forming the gate structure on the semiconductor substrate according to claim 11, wherein the gate structure contacts the first and second impurity regions.

13. The method of claim 11, wherein the first insulation layer is formed with a thickness of about 0.5 nm through 2 nm.

14. The method of claim 11, wherein the second insulation layer includes at least one material selected from the group including Si₃N₄, HfO₂, ZrO₂, TiO₂, Y₂O₃, La₂O₃, and ZrSiO₄.

15. The method of claim 14, wherein the second insulation layer is formed to a thickness of about 4 nm through 10 nm.

16. The method of claim 11, wherein the nanodots include at least one of a metal and a semiconductor material.

17. The method of claim 16, wherein the metal is selected from the group consisting of Ni, Cu, Pd, Au, Ag, Fe, Co, Mn, Cr, V, Mo, Nb and Ru.

18. The method of claim 16, wherein the semiconductor material is selected from the group consisting of Si and Se.

19. The method of claim 11, wherein the third insulation layer includes a material whose permittivity is greater than that of the first insulation layer.

20. The method of claim 19, wherein the third insulation layer includes at least one material selected from the group including SiO₂, A1₂O₃, Si₃N₄, HfO₂, ZrO₂, TiO₂, Y₂O₃, La₂O₃, and ZrSiO₄.
